(19) United States
(12) Patent Application Publication
(10) Pub. No.: US 2007/0217467 A1
(43) Pub. Date: Sep. 20, 2007

(54) Laser diode package utilizing a laser diode stack

(75) Inventors: Mark Joseph DeFranza, Ridgefield, WA (US); David Clifford Dawson, Brush Prairie, WA (US); Jason Nathaniel Farmer, Vancouver, WA (US)

Correspondence Address: PATENT LAW OFFICE OF DAVID G. BECK, P. O. BOX 1146, MILL VALLEY, CA, 94942, US

(73) Assignee: nLight Photonics Corporation, Vancouver, WA (US)

(21) Appl. No.: 11/384,940

(22) Filed: Mar. 20, 2006

(51) Int. Cl. H01S 5/00

(52) U.S. Cl. 372/50.12

(57) ABSTRACT

A laser diode package is provided. The laser diode package includes a plurality of laser diode submount assemblies, each assembly including a submount to which one or more laser diodes are attached. An electrically isolating pad is attached to the same surface of the submount as the laser diode. A metallization layer is deposited onto the outermost surface of the electrically isolating pad, to which an electrical contact pad is bonded. Electrical interconnects, such as wire or ribbon interconnects, connect the laser diode or diodes to the metallization layer. Preferably the laser diode stack is formed by electrically and mechanically bonding together the bottom surface of each submount to the electrical contact pad of an adjacent submount assembly. The laser diode stack is thermally coupled to a cooling block. Preferably thermally conductive and electrically isolating members are interposed between the laser diode stack and the cooling block.

### FIELD OF THE INVENTION

The present invention relates generally to semiconductor lasers and, more particularly, to a laser diode package that provides improved performance and reliability.

### BACKGROUND OF THE INVENTION

High power laser diodes have been used individually and in arrays in a wide range of applications including materials processing, medical devices, printing/imaging systems and the defense industry. Furthermore due to their size, efficiency and wavelength range, they are ideally suited as a pump source for high power solid state lasers. Unfortunately reliability issues have prevented their use in a number of critical applications such as space-based systems in which launch costs coupled with the inaccessibility of the systems once deployed requires the use of high reliability components.

During operation, a laser diode produces excessive heat which can lead to significant wavelength shifts, premature degradation and sudden failure if not quickly and efficiently dissipated. These problems are exacerbated in a typical laser diode pump array in which the laser diode packing density reduces the area available for heat extraction. Additionally as most high energy pulse lasers require a qausi-CW (QCW) laser diode pump, the extreme thermal cycling of the laser diode active regions typically leads to an even greater level of thermal-mechanical stress induced damage.

One approach to overcoming some of the afore-mentioned problems is a laser diode package (e.g., a G package) in which an efficient heat extracting substrate (e.g., beryllium oxide, copper, copper tungsten, etc.) includes multiple grooves into which individual laser diode bars are soldered using an indium solder. Although this package has improved heat dissipation capabilities, it still suffers from numerous problems. First, the coefficient of thermal expansion (CTE) of the solder does not provide a good match with that of the substrate, leading to solder delamination during thermal cycling. Solder delamination is problematic due to the high drive currents that the solder must conduct into the laser diode as well as the heat which the solder must efficiently transfer from the laser diode to the heat extracting substrate. Second, it is difficult to test the individual laser diode bars before installing them into the grooved substrate, potentially leading to arrays in which one or more of the laser diode bars is defective (i.e., non-operational or out of spec.). Third, mounting the laser diode bars into the individual grooves of the substrate may lead to further stresses if the laser diode bars exhibit any curvature.

Accordingly what is needed in the art is an alternate laser diode package that overcomes the problems inherent in the laser diode packages of the prior art, thereby providing improved reliability and performance. The present invention provides such a laser diode package.

### SUMMARY OF THE INVENTION

The present invention provides a laser diode package which includes a stack, either a horizontal stack or a vertical stack, of laser diode submount assemblies. Each laser diode submount assembly is comprised of a submount to which one or more laser diodes are attached. Exemplary laser diodes include single mode single emitter laser diodes, broad area multi-mode single emitter laser diodes, and multiple single emitters fabricated on either a single substrate or on multiple substrates. Preferably the submount has a high thermal conductivity and a CTE that is matched to that of the laser diode. In an exemplary embodiment the submount is fabricated from 90/10 tungsten copper and the laser diode is attached to the submount with a gold-tin solder. An electrically isolating pad is attached to the same surface of the submount as the laser diode. A metallization layer is deposited onto the outermost surface of the electrically isolating pad, to which an electrical contact pad is bonded. Electrical interconnects, such as wire or ribbon interconnects, connect the single emitter laser diode to the metallization layer. Preferably the laser diode stack is formed by electrically and mechanically bonding together the bottom surface of each submount to the electrical contact pad of an adjacent submount assembly, for example using a silver-tin solder.

To provide package cooling, the laser diode stack is thermally coupled to a cooling block, the cooling block preferably including a slotted region into which the laser diode stack fits. In at least one preferred embodiment of the invention, thermally conductive and electrically isolating members are first bonded to the bottom and side surfaces of each submount and then bonded to the cooling block, the members being interposed between the laser diode stack and the cooling block. Preferably the cooling block is comprised of a pair of members, thus insuring good thermal coupling between the laser diode stack and the cooling block.

A further understanding of the nature and advantages of the present invention may be realized by reference to the remaining portions of the specification and the drawings.

### BRIEF DESCRIPTION OF THE DRAWINGS

FIG. 1 is a perspective view of laser diode submount assembly in accordance with the invention;

FIG. 2 is a perspective view of a laser diode stack comprised of multiple submount assemblies;

FIG. 3 shows an end view of a typical laser bar according to the prior art;

FIG. 4 shows an end view of the laser diode stack of FIG. 2;

FIG. 5 shows an end view of a laser diode stack in accordance with the invention, the stack including ten submount assemblies and in which each assembly includes three emitters;

FIG. 6 is a perspective view of the laser diode stack of FIG. 2 along with an electrically isolating backplane member;

FIG. 7 is a perspective view of the laser diode stack of FIG. 6 along with electrically isolating side frame members and a pair of contact assemblies; and

FIG. 8 is a perspective view of the laser diode stack of FIG. 7 attached to a cooling block.

### DESCRIPTION OF THE SPECIFIC EMBODIMENTS

The present invention provides a vertical or horizontal stack of laser diode submount assemblies, each submount assembly including at least one laser diode. In a preferred embodiment, each laser diode of each submount assembly operates at the same wavelength. In an alternate embodiment, the laser diode or diodes of each submount assembly operate at a different wavelength. In yet another alternate embodiment, the stack includes groups of laser diodes where each group operates at a preset wavelength (e.g., 635 nm, 808 nm, 975 nm, 1470 nm, 1900 nm, etc.). It will be appreciated that there are a variety of possible configurations depending upon the number of desired wavelengths and the number of submount assemblies within the laser diode package.

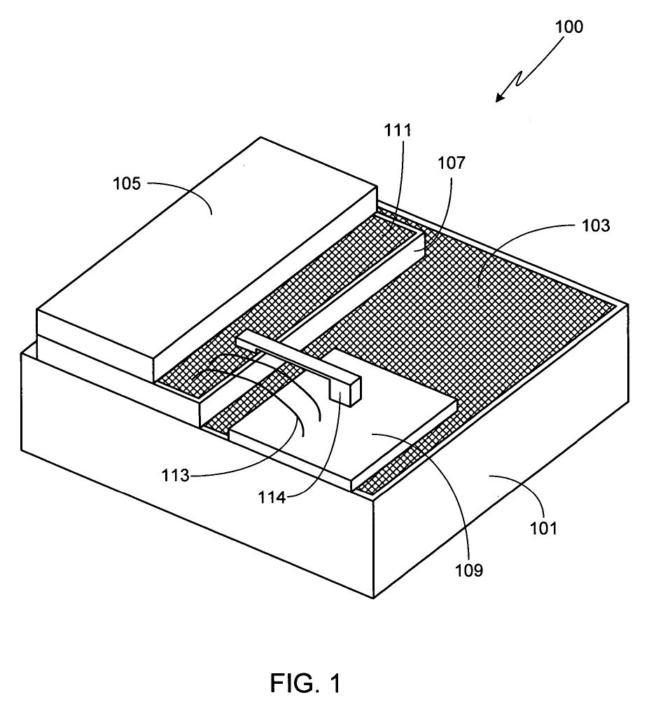

FIG. 1 is an illustration of a single laser diode submount assembly 100. To achieve the desired levels of performance and reliability, preferably submount 101 is comprised of a material with a high thermal conductivity and a CTE that is matched to that of the laser diode. Exemplary materials include copper, copper tungsten, copper molybdenum, and a variety of matrix metal and carbon composites. In a preferred embodiment, a 90/10 tungsten copper alloy is used. On the upper surface of submount 101 is a layer 103 of a bonding solder. Solder layer 103 is preferably comprised of gold-tin, thus overcoming the reliability issues associated with the use of indium solder as a means of bonding the laser diode to the substrate.

On top of submount 101 is a spacer. In the preferred embodiment, the spacer is comprised of a first contact pad 105, preferably used as the N contact for the laser diode, and an electrically insulating isolator 107 interposed between contact pad 105 and submount 101. Preferably insulating isolator 107 is attached to submount 101 via solder layer 103. Preferably contact pad 105 is attached to isolator 107 using the same solder material as that of layer 103 (e.g., Au—Sn solder). Also mounted to submount 101 via solder layer 103 is a laser diode 109. Exemplary laser diodes include both single mode single emitter laser diodes and broad area multi-mode single emitter laser diodes. Additionally, multiple single emitters, either fabricated on individual substrates or on a single substrate, can be mounted to submount 101, thereby forming an array of single emitters on a single submount assembly. The inventors do not envision the use of laser bars with the submount assemblies of the invention, due both to the size of laser bars (i.e., 1 centimeter) and their poor heat dissipation characteristics that result from close emitter packing. In this embodiment of the invention one contact of laser diode 109, preferably the P contact, is made via submount 101, while the second contact, preferably the N contact, is made using wire bonds, ribbon bonds, or other electrical connector which couple the laser diode to metallization layer 111. For illustration purposes, both representative wire bonds 113 and a representative contacting member 114 are shown in FIG. 1, although it will be appreciated that in a typical application only a single type of electrical connector would be used.

After completion of submount assembly 100, preferably the laser diode or diodes 109 attached to the submount are tested. Early testing, i.e., prior to assembly of the entire laser diode package, offers several advantages over testing after package completion. First, it allows defective laser diodes to be identified prior to package assembly, thus minimizing the risk of completing a package assembly only to find that it does not meet specifications due to one or more defective laser diodes. Thus the present package assembly improves on assembly fabrication efficiency, both in terms of time and materials. Second, early testing allows improved matching of the performance of the individual laser diodes within an assembly, for example providing a means of achieving improved wavelength matching between laser diodes or allowing laser diodes operating at different wavelengths to be coupled together in the desired order.

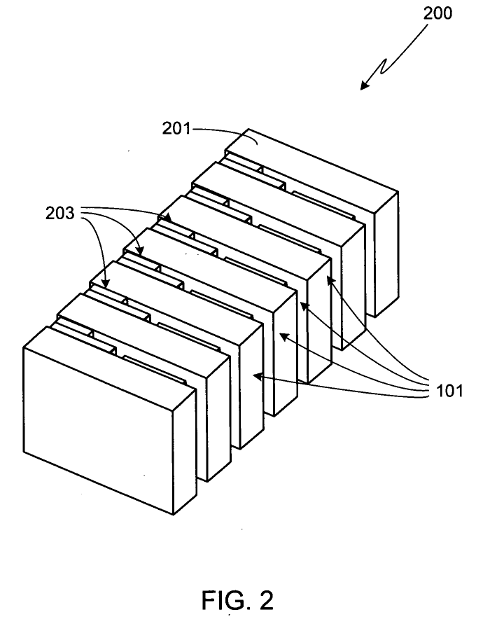

During the next series of steps the laser diode package, which is comprised of a stack of laser diode submount assemblies 100, is fabricated. The perspective view of FIG. 2 shows a stack 200 comprised of six submount assemblies 100 along with an additional submount 201. Although laser diode stack 200 can be fabricated without additional submount 201, the inventors have found that it improves the mechanical reliability of the laser diode package. It will be appreciated that the single emitter stack can utilize fewer, or greater, numbers of submount assemblies 100 and that either horizontal or vertical stack assemblies can be fabricated.

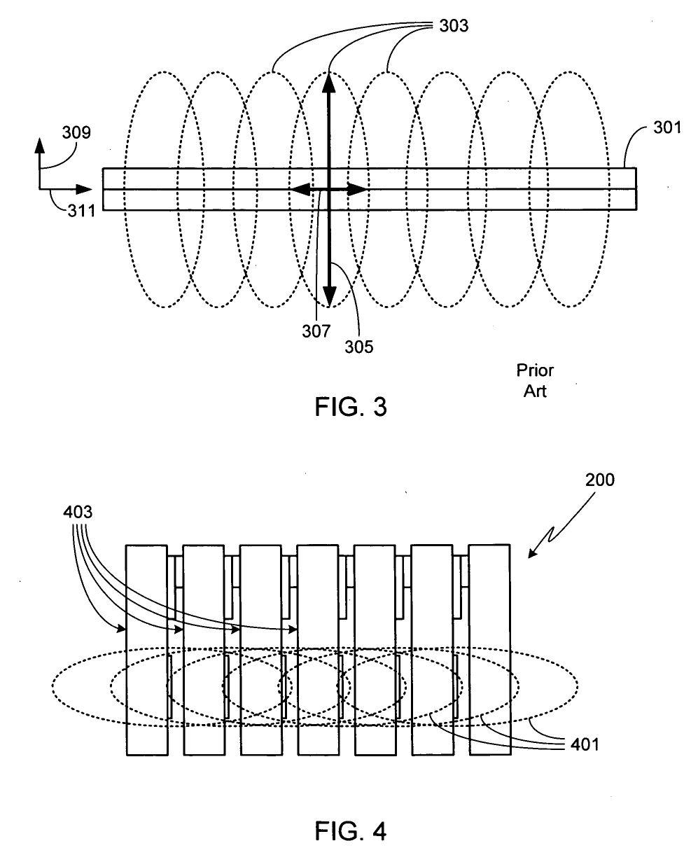

One advantage of the laser diode package of the present invention is illustrated in FIGS. 3-5. FIG. 3 shows the end view of a laser bar 301 such as that typically used for laser pumping or other high power laser diode applications. As shown, each emitter within the laser bar emits an elliptical beam 303 with the fast axis 305 perpendicular to the diode junction and the slow axis 307 parallel to the diode junction. Thus the combination of the individual output beams from laser bar 301 creates an output that is rapidly diverging along axis 309 and is on the order of 1 centimeter, the length of a laser bar, along axis 311. Note that for illustration clarity, only 8 beams 303 are shown in FIG. 3 although it will be appreciated that a typical laser bar includes many more emitters.

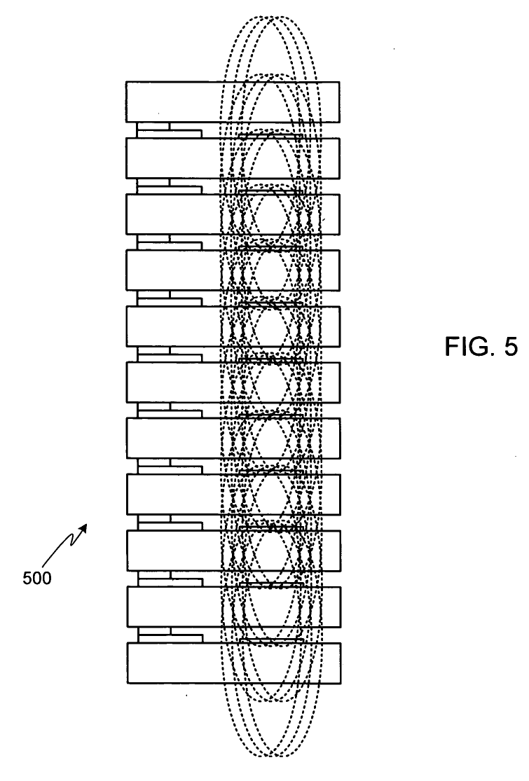

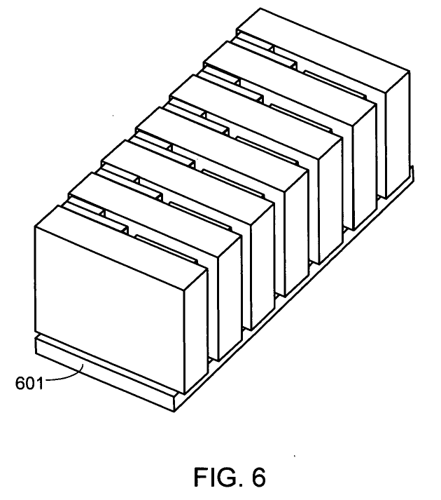

FIG. 4 is an end view of the output from laser diode stack 200. In this figure it is assumed that each diode laser 109 is a single emitter, although as described herein the invention is not so limited. In marked contrast to the output beam from laser bar 301, the fast axis of the output beams 401 from the laser diode stack subassemblies are co-aligned (i.e., the fast axis of each output beam 401 is approximately perpendicular to the submount mounting surface 403). In addition to providing improved beam geometry for many applications, the present invention provides a simple means of controlling the dimensions of the output beam by varying the number of subassemblies within the stack as well as the number of emitters per laser diode. For example, laser diode stack 500 shown in FIG. 5 includes 10 subassemblies with each laser diode having three emitters. Additionally, the present invention provides improved heat dissipation, the ability to vary the wavelength between subassemblies, and individual laser diode addressability.

In a preferred embodiment of the invention, laser diodes 109 are serially coupled together. In this embodiment the individual submount assemblies 100 are combined into a single assembly by bonding the upper surface of each contact pad 105 to a portion of the lower surface of the adjacent submount 101, submounts 101 being comprised of an electrically conductive material. Preferably solder 203 coupling contact pads 105 to submounts 101 has a lower melting temperature than the solder used to fabricate submount assembly 101, thus insuring that during this stage of assembly the reflow process used to combine the submount assemblies will not damage the individual assemblies. In a preferred embodiment of the invention, a silver-tin solder is used with a melting temperature lower than that of the Au—Sn solder preferably used for solder joint 203.

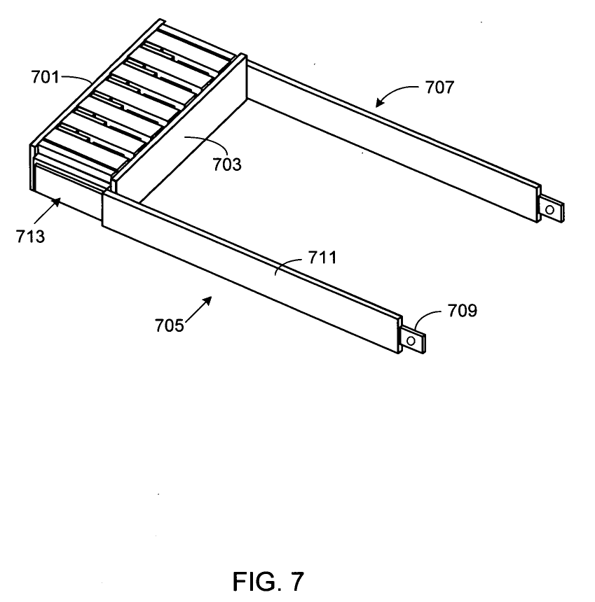

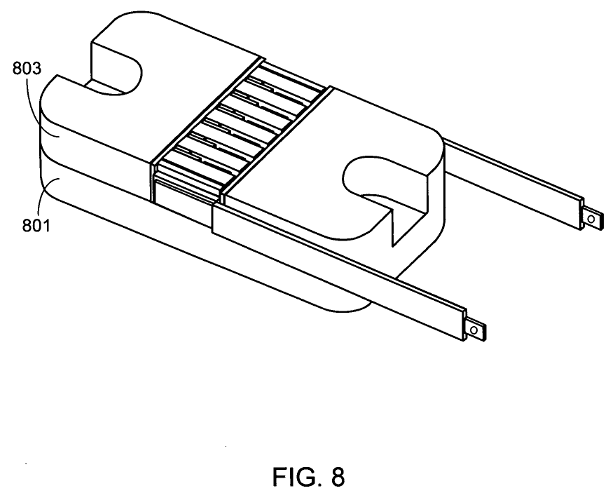

In the next series of processing steps, illustrated in FIGS. 6 and 7, an electrically isolating backplane member 601 as well as electrically isolating side frame members 701 and 703 are attached to the back surface and the side surfaces, respectively, of submounts 101. In the preferred embodiment members 601, 701 and 703 are fabricated from beryllium oxide, a material that is both thermally conductive and electrically isolating. It will be appreciated that other thermally conductive/electrically isolating materials, such as aluminum nitride, CVD diamond or silicon carbide, can be used for members 601, 701 and 703. Preferably the solder used to attach members 601, 701 and 703 to submounts 101 has a lower melting temperature than that used to couple together submount assemblies 101 (i.e., solder 203). Accordingly in at least one embodiment a tin-indium-silver solder is used.

In an alternate embodiment of the invention laser diodes 109 are not serially coupled together, rather they are coupled together in parallel, or they are individually addressable. Individual addressability allows a subset of the total number of laser diodes within the stack to be activated at any given time. In order to achieve individual addressability, or to couple the laser diodes together in a parallel fashion, the electrically conductive path between individual submount assemblies must be severed, for example using a pad 105 that is not electrically conductive, and/or using a submount 101 that is not electrically conductive, and/or placing an electrically isolating layer between submounts 101 and pads 105 within assembly 200. Parallel connections as well as individual laser diode connections can be made, for example, by coupling interconnect cables to metallization layers 103 and 111. Additionally one or more of members 601, 701 and 703 can be patterned with electrical conductors, thus providing convenient surfaces for the inclusion of circuit boards that can simplify the relatively complex wiring needed to provide individual laser diode addressability.

In the preferred package assembly process and assuming that the laser diode subassemblies are serially coupled together, the same mounting fixture that is used to attach side members 701 and 703 to submounts 101 is also used to attach contact assemblies 705 and 707 to the laser diode package. Preferably contact assemblies 705 and 707 are assembled in advance using a higher melting temperature solder such as a gold-tin solder. Each contact assembly 705/707 includes a wire 709, covered with an insulator 711 (e.g., Kapton), and a contact (or contact assembly) 713.

In the preferred embodiment, the laser diode submount stack assembly, shown in FIGS. 6 and 7, is attached to a cooler body as illustrated in FIG. 8. Preferably the cooler body is comprised of two parts; a primary member 801 and a secondary member 803. The benefit of having two members 801/803 rather than a single slotted member is that it is easier to achieve a closer fit between the cooler body and the laser diode submount stack assembly, thus insuring more efficient heat transfer and thus assembly cooling. Preferably bottom member 601 and side members 701 and 703 are soldered to members 801/803 of the cooler body, thus insuring a mechanically robust assembly.

As will be understood by those familiar with the art, the present invention may be embodied in other specific forms without departing from the spirit or essential characteristics thereof. Accordingly, the disclosures and descriptions herein are intended to be illustrative, but not limiting, of the scope of the invention which is set forth in the following claims.

What is claimed is:

1. A laser diode package comprising:
a plurality of laser diode submount assemblies, wherein each of said plurality of laser diode submount assemblies comprises:
a submount;
at least one laser diode attached to a first portion of a first surface of said submount, wherein a fast axis corresponding to an output beam of said at least one laser diode is approximately perpendicular to said first surface of said submount; and
a spacer attached to a second portion of said first surface of said submount; and
means for mechanically coupling each laser diode submount assembly spacer to a second surface of said submount of an adjacent laser diode submount assembly.

2. The laser diode package of claim 1, further comprising a cooling block in thermal communication with each submount of said plurality of laser diode submount assemblies.

3. The laser diode package of claim 2, further comprising a backplane member interposed between a back surface of each submount of said plurality of laser diode submount assemblies and said cooling block.

4. The laser diode package of claim 3, wherein said backplane member is comprised of an electrically isolating material.

5. The laser diode package of claim 4, wherein said electrically isolating material is selected from the group consisting of aluminum nitride, beryllium oxide, CVD diamond and silicon carbide.

6. The laser diode package of claim 2, further comprising a side frame member interposed between a side surface of each submount of said plurality of laser diode submount assemblies and said cooling block.

7. The laser diode package of claim 6, wherein said side frame member is comprised of an electrically isolating material.

8. The laser diode package of claim 7, wherein said electrically isolating material is selected from the group consisting of aluminum nitride, beryllium oxide, CVD diamond and silicon carbide.

9. The laser diode package of claim 2, further comprising:
a backplane member interposed between a back surface of each submount of said plurality of laser diode submount assemblies and said cooling block;
a first side frame member interposed between a first side surface of each submount of said plurality of laser diode submount assemblies and said cooling block; and
a second side frame member interposed between a second side surface of each submount of said plurality of laser diode submount assemblies and said cooling block.

10. The laser diode package of claim 2, wherein said cooling block is comprised of a first member and a second member, wherein said first and second cooling block members form a slotted region, and wherein said plurality of laser diode submount assemblies fit within said slotted region.

11. The laser diode package of claim 1, wherein each submount of said plurality of laser diode submount assemblies is comprised of an electrically conductive material.

12. The laser diode package of claim 11, wherein said electrically conductive material is selected from the group consisting of copper, copper tungsten, copper molybdenum, matrix metal composites and carbon composites.

13. The laser diode package of claim 1, further comprising a solder layer interposed between each of said at least one laser diode and said first portion of said first surface of each submount of said plurality of laser diode submount assemblies.

14. The laser diode package of claim 1, said spacer further comprising an electrical isolator attached to said second portion of said first surface of said submount and an electrical contact pad attached to said electrical isolator.

15. The laser diode package of claim 14, further comprising a metallization layer deposited on a top surface of said electrical isolator of each of said plurality of laser diode submount assemblies, wherein said electrical contact pad is in electrical communication with said metallization layer.

16. The laser diode package of claim 15, further comprising at least one wire bond coupling said at least one laser diode and said metallization layer of each of said plurality of laser diode submount assemblies.

17. The laser diode package of claim 15, further comprising at least one ribbon bond coupling said at least one laser diode and said metallization layer of each of said plurality of laser diode submount assemblies.

18. The laser diode package of claim 14, wherein said mechanically coupling means further comprises means for electrically connecting each electrical contact pad to said second surface of said submount of said adjacent laser diode submount assembly.

19. The laser diode package of claim 18, wherein said electrically connecting means is comprised of a solder layer.

20. The laser diode package of claim 1, wherein said at least one laser diode of said plurality of laser diode submount assemblies is a single mode single emitter laser diode.

21. The laser diode package of claim 1, wherein said at least one laser diode of said plurality of laser diode submount assemblies is a broad area multi-mode single emitter laser diode.

22. The laser diode package of claim 1, wherein said at least one laser diode of said plurality of laser diode submount assemblies is comprised of multiple single emitters on multiple substrates.

23. The laser diode package of claim 1, wherein said at least one laser diode of said plurality of laser diode submount assemblies is comprised of multiple single emitters on a single substrate.

24. The laser diode package of claim 1, wherein the fast axis of each laser diode is co-aligned with the fast axis of a corresponding laser diode on said adjacent laser diode submount assembly.

25. A laser diode package comprising:
a plurality of laser diode submount assemblies, wherein each of said plurality of laser diode submount assemblies comprises:
a submount;
at least one laser diode attached to a first portion of a first surface of said submount, wherein a fast axis corresponding to an output beam of said at least one laser diode is approximately perpendicular to said first surface of said submount;
an electrical isolator, wherein a first surface of said electrical isolator is attached to a second portion of said first surface of said submount;
a metallization layer on a second surface of said electrical isolator;
an electrical contact pad attached to said second surface of said electrical isolator; and
an electrical interconnect coupling said metallization layer and said at least one laser diode;
means for forming a laser diode stack from said plurality of laser diode submount assemblies, said forming means further comprising a bonding layer electrically coupling each electrical contact pad to a second surface of said submount of an adjacent laser diode submount assembly; and
a cooling block in thermal communication with each submount of said plurality of laser diode submount assemblies.

26. The laser diode package of claim 25, further comprising:
an electrically isolating backplane member interposed between a back surface of each submount of said plurality of laser diode submount assemblies and said cooling block;
an electrically isolating first side frame member interposed between a first side surface of each submount of said plurality of laser diode submount assemblies and said cooling block; and
an electrically isolating second side frame member interposed between a second side surface of each submount of said plurality of laser diode submount assemblies and said cooling block.

27. The laser diode package of claim 26, wherein said electrically isolating backplane member, first side frame member, and second side frame member are comprised of a material selected from the group consisting of aluminum nitride, beryllium oxide, CVD diamond and silicon carbide.

28. The laser diode package of claim 25, wherein said each submount of said plurality of laser diode submount assemblies is comprised of an electrically conductive material selected from the group consisting of copper, copper tungsten, copper molybdenum, matrix metal composites and carbon composites.

29. The laser diode package of claim 25, further comprising a gold-tin solder layer interposed between each of said at least one laser diode and said first portion of said first surface of each submount of said plurality of laser diode submount assemblies.

30. The laser diode package of claim 25, wherein said at least one laser diode of said plurality of laser diode submount assemblies is a single mode single emitter laser diode.

31. The laser diode package of claim 25, wherein said at least one laser diode of said plurality of laser diode submount assemblies is a broad area multi-mode single emitter laser diode.

32. The laser diode package of claim 25, wherein said at least one laser diode of said plurality of laser diode submount assemblies is comprised of multiple single emitters on multiple substrates.

33. The laser diode package of claim 25, wherein said at least one laser diode of said plurality of laser diode submount assemblies is comprised of multiple single emitters on a single substrate.

34. The laser diode package of claim 25, wherein said cooling block is comprised of a first member and a second member, wherein said first and second cooling block members form a slotted region, and wherein said laser diode stack fits within said slotted region.
